(19) United States
(12) Patent Application Publication
(10) Pub. No.: US 2026/0333706 A1
(43) Pub. Date: Oct. 22, 2026

(54) SYSTEMS AND METHODS FOR FERROELECTRIC RANDOM ACCESS MEMORY (FERAM) DEVICE ARCHITECTURE

(71) Applicant: Samsung Electronics Co., Ltd., Suwon-si (KR)

(72) Inventors: Mehdi Saremi, Danville, CA (US); Muhammed Ahosan Ul Karim, San Jose, CA (US)

(21) Appl. No.: 19/314,829

(22) Filed: Aug. 29, 2025

Related U.S. Application Data
(60) Provisional application No. 63/790,449, filed on Apr. 17, 2025.

(51) Int. Cl. H10B 53/30

(52) U.S. Cl. CPC H10B 53/30

(57) ABSTRACT

A semiconductor device includes a substrate having a shallow trench isolation region; and a ferroelectric random-access memory device including a first transistor, a second transistor, and a ferroelectric capacitor. The ferroelectric capacitor is on the shallow trench isolation region and the first and second transistors are adjacent to the shallow trench isolation region.

### CROSS-REFERENCE TO RELATED APPLICATION(S)

The present application claims priority to and the benefit of U.S. Provisional Application No. 63/790,449 entitled “Fully Front-End of Line (FEOL) Ferroelectric Random Access Memory (FeRAM) for Advanced Technology Nodes,” filed Apr. 17, 2025, the entire content of which is incorporated herein by reference.

### FIELD

The present disclosure relates to ferroelectric random-access memory and methods of manufacturing the same.

### BACKGROUND

The advancement of semiconductor technology continues to drive the need for transistor architectures that support increased device density, enhanced performance, and reduced power consumption at progressively smaller technology nodes. As process geometries scale, transistor designs incorporating gate structures that provide improved electrostatic control over the channel region may be utilized to address challenges associated with short-channel effects, leakage currents, and overall device reliability.

A variety of different types of memory architectures exist, including magnetoresistive random access memory (MRAM), ferroelectric random-access memory (FeRAM), dynamic random access memory (DRAM), and static random access memory (SRAM). MRAM and FeRAM are both non-volatile forms of memory whereas both DRAM and SRAM are volatile forms of memory that lose data when power is not supplied. Additionally, FeRAM is a type of memory that utilizes a capacitor having a ferroelectric material, such as lead zirconate titanate (PZT), to store data. Ferroelectric materials are configured to hold an electric polarization that can be switched from two polarization states, positive and negative. In operation, to write data to FeRAM, a positive voltage may be applied to the ferroelectric capacitor to store a “1” value and a negative voltage may be applied to the ferroelectric capacitor to store a “0” value. To read a bit from the FeRAM, a positive voltage is applied to the ferroelectric capacitor and the amount of current that flows indicates the value of the bit (a relatively higher current indicates a “1” value and a relatively lower current indicates a “0” value).

The above information disclosed in this Background section is only to enhance understanding of background information pertaining to the present disclosure and may contain information that does not constitute prior art.

### SUMMARY

The present disclosure relates to various embodiments of a semiconductor device. In one embodiment, the semiconductor device includes a substrate having a shallow trench isolation region, a ferroelectric random-access memory device having a first transistor, a second transistor, and a ferroelectric capacitor on the shallow trench isolation region. The first and second transistors are adjacent to the shallow trench isolation region.

The shallow trench isolation region may include a dielectric material.

The shallow trench isolation region may be a single diffusion break or a double-diffusion break.

A width of the shallow trench isolation region may be equal to or less than a threshold distance, such as approximately 1 contacted poly pitch (CPP).

The semiconductor device may also include a single V_{DD} rail including both VDD and VSS voltage supplies coupled to the two-transistor one-capacitor ferroelectric random-access memory device.

The ferroelectric capacitor may include a ferroelectric layer between a pair of electrodes.

The ferroelectric layer may include a ferroelectric material such as hafnium-zirconium oxide (HZO), lead zirconate titanate (PZT), bismuth ferrite (BiFeO3), lithium niobate (LiNbO3), barium titanate (BaTiO3), triglycine sulfate, lithium tantalate, polyvinylidene fluoride (PVDF), and/or Rochelle salt.

The pair of electrodes may include a material such as a metal, a conductive oxide, and/or graphene.

The present disclosure also relates to various embodiments of an electronic device including the semiconductor device. The electronic device may be a memory, an application specific integrated circuit (ASIC), a central processing unit (CPU), a field programmable gate array (FPGA), or a graphics processing unit (GPU).

The present disclosure also relates to various embodiments of a method of manufacturing a semiconductor device. In one embodiment, the method includes forming a first transistor of a ferroelectric random-access memory device on a substrate during a front-end-of-line process; forming a second transistor of the ferroelectric random-access memory device on the substrate during the front-end-of-line process, the first transistor and the second transistor being adjacent to a shallow trench isolation region in the substrate; and forming a ferroelectric capacitor on the shallow trench isolation region, including forming a pair of electrodes and forming an annealed ferroelectric layer between the pair of electrodes.

In general, higher annealing temperatures may result in higher ferroelectric polarization.

The ferroelectric layer may be a ferroelectric material such as hafnium-zirconium oxide (HZO), lead zirconate titanate (PZT), bismuth ferrite (BiFeO3), lithium niobate (LiNbO3), barium titanate (BaTiO3), triglycine sulfate, lithium tantalate, polyvinylidene fluoride (PVDF), or Rochelle salt.

The method may also include forming interconnects in a back-end-of-line process after the front-end-of-line process.

The present disclosure also relates to various embodiments of a system including an electronic device. The electronic device includes a semiconductor device, and the semiconductor device includes a substrate having a shallow trench isolation region; and a ferroelectric random-access memory device including a first transistor, a second transistor, and a ferroelectric capacitor. The ferroelectric capacitor is on the shallow trench isolation region, and the first and second transistors are adjacent to the shallow trench isolation region.

The shallow trench isolation region may include a single diffusion break or a double-diffusion break.

A width of the shallow trench isolation region may be equal to or less than a threshold distance, such as 1 CPP.

The semiconductor device may include a single V_{DD} rail including both VDD and VSS voltage supplies coupled to the ferroelectric random-access memory device.

The ferroelectric layer may include a ferroelectric material such as hafnium-zirconium oxide (HZO), lead zirconate titanate (PZT), bismuth ferrite (BiFeO3), lithium niobate (LiNbO3), barium titanate (BaTiO3), triglycine sulfate, lithium tantalate, polyvinylidene fluoride (PVDF), or Rochelle salt.

The electronic device may be a memory, an application specific integrated circuit (ASIC), a central processing unit (CPU), a field programmable gate array (FPGA), or a graphics processing unit (GPU).

This summary is provided to introduce a selection of concepts that are further described below in the detailed description. This summary is not intended to identify key or essential features of the claimed subject matter, nor is it intended to be used in limiting the scope of the claimed subject matter. One or more of the described features may be combined with one or more other described features to provide a workable method or device.

### BRIEF DESCRIPTION OF THE DRAWINGS

The patent or application file contains at least one drawing executed in color. Copies of this patent or patent application publication with color drawing(s) will be provided by the Office upon request and payment of the necessary fee.

The features and advantages of embodiments of the present disclosure will be better understood by reference to the following detailed description when considered in conjunction with the accompanying figures. In the figures, like reference numerals are used throughout the figures to reference like features and components. The figures are not necessarily drawn to scale.

FIG. 1 is a side view of a ferroelectric random-access memory (FeRAM) device according to one embodiment of the present disclosure;

FIG. 2A is a graph comparing the polarization of FeRAM devices polarized at different temperatures during manufacturing according to embodiments of the present disclosure;

FIG. 2B is a graph comparing the polarization of FeRAM devices having different ferroelectric capacitor thicknesses according to embodiments of the present disclosure;

FIG. 3 is a flowchart illustrating tasks of a method of manufacturing a FeRAM device according to one embodiment of the present disclosure; and

FIG. 4 is a schematic view of a semiconductor device including a FeRAM device according to one embodiment of the present disclosure.

### DETAILED DESCRIPTION

Ferroelectric random-access memory (FeRAM) may be provided in various configurations, such as a one-transistor one-capacitor (“1T1C”) configuration or a two-transistor one-capacitor (“2T1C”). In a related art 1T1C device, the transistor may be manufactured during the front-end-of-line (FEOL) process and the capacitor may be manufactured during the back-end-of-line (BEOL) process. In a related art 2T1C device, one of the transistors may be manufactured during the FEOL process and the other transistor and the capacitor may be manufactured during the BEOL process. The FEOL process in semiconductor manufacturing is the process of fabricating individual components (e.g., transistors, capacitors, and/or resistors) on (or in) a semiconductor substrate, and the BEOL process is the subsequent process of depositing metal interconnect layers to connect the components that were formed in the FEOL process.

Ferroelectric (Fe) films utilized in FeRAM may require a high rapid thermal annealing (RTA) above 500 °C to acquire a large remnant polarization (2 Pr>40 μC/cm²), a large memory window (>0.4V), and a large endurance (>1e11). However, such high annealing temperatures degrade the reliability of the components manufactured during the BEOL process if the Fe cap is manufactured in the BEOL process. Accordingly, related art FeRAM devices manufactured during the BEOL process have a low Fe polarization, which reduces performance. Additionally, related art FeRAM devices require a relatively high operating voltage and multiple supply voltages (multi-Vdd) and are relatively difficult to scale.

The present disclosure relates to various embodiments of a FeRAM device. In one or more embodiments, the FeRAM device can include a two-transistor one-capacitor (2T1C) FeRAM array that is manufactured during the FEOL process of fabricating the semiconductor device (e.g., memory device). Incorporating the FeRAM device into the FEOL process enables higher temperature annealing during manufacturing, which increases the ferroelectric (Fe) polarization and the memory window of the FeRAM device, that would otherwise degrade BEOL reliability if the FeRAM device were instead incorporated into the BEOL process. Fe polarization refers to the alignment of the electric dipoles in the ferroelectric material in one of two states, which can be switched with the application of an electric charge and which are retained following the removal of the electric charge. As used herein, the memory window refers to the size of the difference between the two polarization states (e.g., the difference between the polarization of the FeRAM device in the “1” state and the polarization of the FeRAM device in the “0” state). Having a relatively large memory window is important to enable the device to distinguish between the different polarization states when reading data (e.g., determining whether the stored data is a “1” or a “0”) and thus the relatively large memory window ensures reliable operation of the memory device. Additionally, incorporating the FeRAM device into the FEOL process permits the use of FEOL processing nodes, which are more advanced and have higher performance (e.g., are faster) than BEOL transistors and thereby increase FeRAM performance. In one or more embodiments, the operating voltage of the FeRAM may be reduced to Vdd and therefore require only a single-Vdd rail design, which is beneficial compared to a related art FeRAM device that requires a higher operating voltage and a multi-Vdd rail design. Furthermore, the FeRAM device according to embodiments of the present disclosure may have higher density and better area scaling compared to related art static random-access memory (SRAM) in the same or similar device. For instance, in one or more embodiments, the FeRAM device of the present disclosure may occupy only approximately 50% of the area that the related art SRAM device occupies.

In the following detailed description, numerous specific details are set forth in order to provide a thorough understanding of the disclosure. It will be understood, however, by those skilled in the art that the disclosed aspects may be practiced without these specific details. In other instances, well-known methods, procedures, components and circuits have not been described in detail to not obscure the subject matter disclosed herein.

Reference throughout this specification to “one embodiment” or “an embodiment” means that a particular feature, structure, or characteristic described in connection with the embodiment may be included in at least one embodiment disclosed herein. Thus, the appearances of the phrases “in one embodiment” or “in an embodiment” or “according to one embodiment” (or other phrases having similar import) in various places throughout this specification may not necessarily all be referring to the same embodiment. Furthermore, the particular features, structures or characteristics may be combined in any suitable manner in one or more embodiments. In this regard, as used herein, the word “exemplary” means “serving as an example, instance, or illustration.” Any embodiment described herein as “exemplary” is not to be construed as necessarily preferred or advantageous over other embodiments. Additionally, the particular features, structures, or characteristics may be combined in any suitable manner in one or more embodiments. Also, depending on the context of discussion herein, a singular term may include the corresponding plural forms and a plural term may include the corresponding singular form. Similarly, a hyphenated term (e.g., “two-dimensional,” “pre-determined,” “pixel-specific,” etc.) may be occasionally interchangeably used with a corresponding non-hyphenated version (e.g., “two dimensional,” “predetermined,” “pixel specific,” etc.), and a capitalized entry (e.g., “Counter Clock,” “Row Select,” “PIXOUT,” etc.) may be interchangeably used with a corresponding non-capitalized version (e.g., “counter clock,” “row select,” “pixout,” etc.). Such occasional interchangeable uses shall not be considered inconsistent with each other.

Also, depending on the context of discussion herein, a singular term may include the corresponding plural forms and a plural term may include the corresponding singular form. It is further noted that various figures (including component diagrams) shown and discussed herein are for illustrative purpose only, and are not drawn to scale. For example, the dimensions of some of the elements may be exaggerated relative to other elements for clarity. Further, if considered appropriate, reference numerals have been repeated among the figures to indicate corresponding and/or analogous elements.

The terminology used herein is for the purpose of describing some example embodiments only and is not intended to be limiting of the claimed subject matter. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

It will be understood that when an element or layer is referred to as being on, “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numerals refer to like elements throughout. As used herein, the term “and/or” includes any and all combinations of one or more of the associated listed items.

The terms “first,” “second,” etc., as used herein, are used as labels for nouns that they precede, and do not imply any type of ordering (e.g., spatial, temporal, logical, etc.) unless explicitly defined as such. Furthermore, the same reference numerals may be used across two or more figures to refer to parts, components, blocks, circuits, units, or modules having the same or similar functionality. Such usage is, however, for simplicity of illustration and ease of discussion only; it does not imply that the construction or architectural details of such components or units are the same across all embodiments or such commonly-referenced parts/modules are the only way to implement some of the example embodiments disclosed herein.

Unless otherwise defined, all terms (including technical and scientific terms) used herein have the same meaning as commonly understood by one of ordinary skill in the art to which this subject matter belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Transistor architectures utilized stacked channel structures and gate-all-around configurations may be utilized to facilitate improved control and scalability. In certain designs, isolation features may be positioned between adjacent devices to enable tighter integration of complementary transistors while maintaining electrical isolation and optimizing gate pitch.

As semiconductor devices evolve toward more advanced nodes, various design considerations arise, including minimizing or reducing parasitic capacitance, ensuring precise gate alignment, managing variability in channel structures, and simplifying fabrication processes. The present disclosure relates to various embodiments of a FeRAM device that is fabricated utilizing the FEOL semiconductor manufacturing process, which enables the ferroelectric material of the FeRAM device to be annealed at a higher temperature than if it were fabricated utilizing the BEOL process and thereby improves the memory window of the FeRAM device.

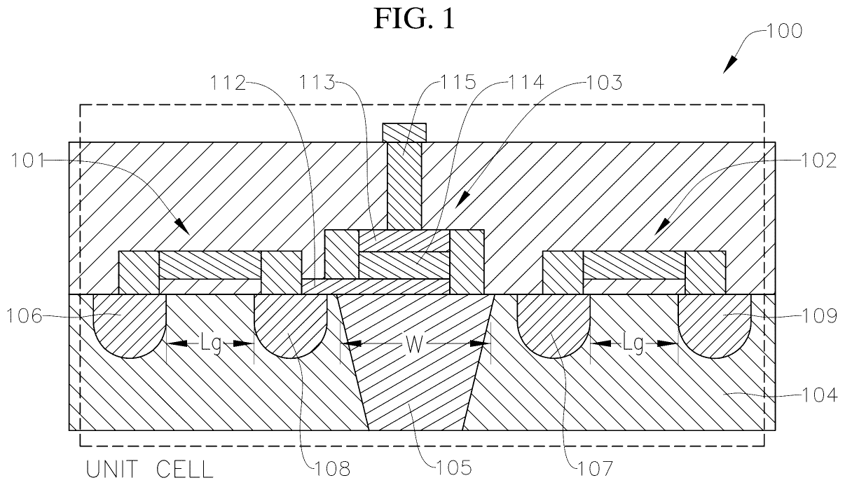

FIG. 1 depicts a FeRAM device 100 manufactured in the FEOL process of a semiconductor device according to one embodiment of the present disclosure. In the illustrated embodiment, the FeRAM device 100 includes a first transistor 101, a second transistor 102, and a ferroelectric capacitor 103 (i.e., the FeRAM device 100 may be a two-transistor one-capacitor (2T1C) FeRAM device). The first and second transistors 101, 102 are located on (or in) a substrate 104 (e.g., a silicon substrate) and adjacent to (e.g., at opposite sides) of a shallow trench isolation (STI) region 105 in the substrate 104. The ferroelectric capacitor 103 is on the STI region 105. In one or more embodiments, the STI region 105 may be a single diffusion break (SDB) or a double-diffusion break (DDB), for example. As used herein, a diffusion break may be a region of an electrically insulating material (dielectric material) (e.g., a trench filled with an oxide material) that is configured to electrically isolate adjacent devices from each other and thereby prevent (or at least mitigate) electrical leakage between the adjacent devices.

In the illustrated embodiment, each of the first and second transistors 101, 102 includes a source region 106, 107, respectively, a drain region 108, 109, respectively, a channel region 110, 111, respectively, between the source region 106, 107 and the drain region 108, 109, and a gate 106, 107, respectively. However, the present disclosure is not limited to any particular length for the gates 106, 107 and the gates 106, 107 may have any other suitable length.

In the illustrated embodiment, the ferroelectric capacitor 103 includes a pair of electrodes 112, 113 (e.g., upper and lower plates 112, 113 spaced apart from each other) and a ferroelectric layer 114 between the pair of electrodes 112, 113 (i.e., the ferroelectric layer 114 is sandwiched between the pair of electrodes 112, 113). The electrodes 112, 113 may be formed of (or include) any suitable material, such as metal (e.g., platinum (Pt), ruthenium (Ru), iridium (Ir), tungsten (W), and/or Titanium nitride (TiN)), a conductive oxide (e.g., ruthenium dioxide (RuO₂), molybdenum dioxide (MoO₂), and/or Indium tin oxide (ITO)), graphite, few-layer graphene (FLG), or combinations thereof. The ferroelectric layer 114 may be formed of (or include) any suitable ferroelectric material, such as hafnium-zirconium oxide (HZO), lead zirconate titanate (PZT), bismuth ferrite (BiFeO3), lithium niobate (LiNbO3), barium titanate (BaTiO3), triglycine sulfate, lithium tantalate, polyvinylidene fluoride (PVDF), and/or Rochelle salt. The ferroelectric material of the ferroelectric layer 114 exhibits spontaneous electric polarization P (i.e., a dipole moment even when an external electric field is not applied). The polarization of the ferroelectric material 114 can be switched between a positive polarization state and a negative polarization state (P+ and P−) by applying an external electric field. In one or more embodiments, the ferroelectric layer 114 may have been annealed at a temperature of approximately 500 °C or more (e.g., approximately 650 °C or more, approximately 800 °C or more, or approximately 1000 °C or more). Annealing is a heat-treatment process in which the ferroelectric material 114 is heated above its recrystallization temperature and then cooled. As described in more detail below, annealing the ferroelectric layer 114 at a relatively high temperature is configured to increase the memory window of the FeRAM device 100 (i.e., the polarization difference between the positive polarization state and the negative polarization state), which is important to enable the FeRAM device 100 to distinguish between the different polarization states and thus ensures reliable operation of the FeRAM device 100 as a non-volatile memory device.

In the illustrated embodiment, one of the electrodes 112 (e.g., the lower plate) of the ferroelectric capacitor 103 is coupled to the drain 108 or the source 106 of the first transistor 101. In the illustrated embodiment, the FeRAM device 100 also includes a via 115 connected to one of the electrodes 113 (e.g., the upper plate) of the ferroelectric capacitor 103. The via 115 is configured to deliver current to the ferroelectric material 114 and thereby set the polarization state (the negative polarization state P− or the positive polarization state P+) of the ferroelectric material 114. In one or more embodiments, any other suitable configuration of the via 115 may be utilized.

In one or more embodiments, the width W of the STI region 105 is equal to or less than approximately 1 contacted poly pitch (CPP) (also known as contacted gate pitch (CGP)). The CPP is the transistor gate pitch between the first transistor 101 and the second transistor 102 (i.e., the spacing between the gate for the first transistor 101 and the gate for the second transistor 102). In one or more embodiments, the CPP may be approximately equal to the width of the STI region 105. Setting the CPP approximately equal to the width of the STI region 105 is configured to reduce the overall width of the FeRAM device 100 and may ensure alignment with other components (e.g., transistors, capacitors, and/or resistors) of the device into which the FeRAM device 100 is incorporated. However, in one or more embodiments, the STI region 105 may have any other suitable width W. For instance, in one or more embodiments, the width W of the STI region 105 may be greater than approximately 1 CPP (e.g., the width W of the STI region 105 may be approximately 2 CPP or more).

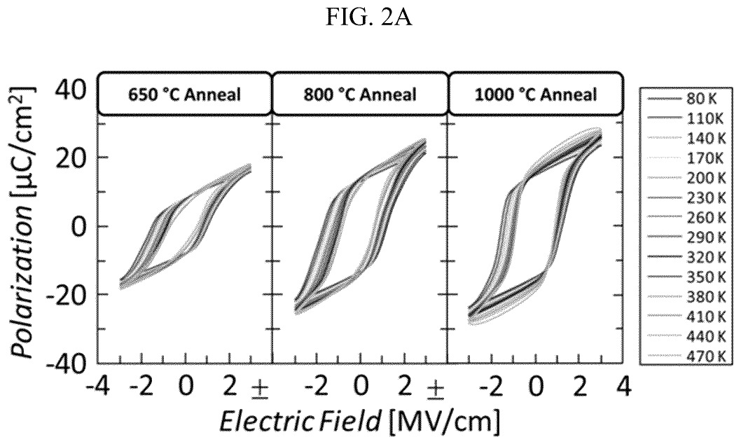

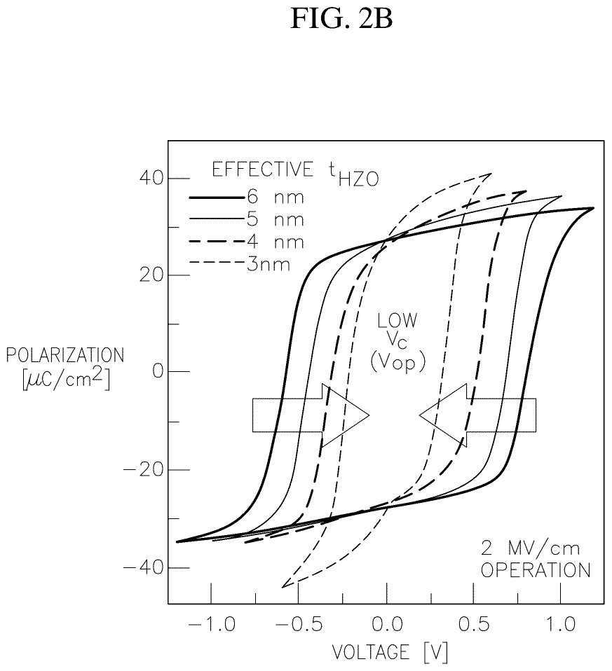

FIG. 2A is a graph depicting the polarization P (in micro coulombs per square centimeter μC/cm²) of an HZO ferroelectric material as a function of the electric field in MV/cm applied to HZO ferroelectric material according to one or more embodiments of the present disclosure. FIG. 2A also depicts the polarization curve as a function of operating temperature (ranging from 80K to 470K). As shown in FIG. 2A, the polarization of the HZO ferroelectric material follows a hysteresis loop, which is an inherent characteristic of ferroelectric materials. As the electric field increases from approximately −3 MV/cm to approximately +3 MV/cm, the polarization P follows the lower curve portion of the loop and as the electric field decreases from approximately +3 MV/cm to approximately −3 MV/cm, the polarization P follows the upper curve portion of the loop, thereby forming a hysteresis loop because the polarization does not follow the same curve as the electric field is increased and decreased. Additionally, FIG. 2A depicts the polarization of an HZO ferroelectric material that has been annealed at a temperature of approximately 650 °C (shown on the left graph), an HZO ferroelectric material that has been annealed at a temperature of approximately 800 °C (shown in the center graph), and an HZO ferroelectric material that has been annealed at a temperature of approximately 1000 °C (shown on the right graph). As shown in FIG. 2A, increasing the annealing temperature from 650 °C to 800 °C increased the polarization window from a range of approximately +18 P to −18 P to a range of approximately +25 P to −25 P and increased the remnant polarization Pr (i.e., the polarization P when no voltage (0 V) is applied) from approximately 10 μC/cm² to approximately 15 μC/cm². Additionally, as shown in FIG. 2A, increasing the annealing temperature from 800 °C to 1000 °C increased the polarization window from a range of approximately +25 P to −25 P to a range of approximately +28 P to −28 P and increased the remnant polarization Pr (i.e., the polarization P when no voltage (0 V) is applied) from approximately 15 μC/cm² to approximately 20 μC/cm². Furthermore, as shown in FIG. 2A, for each of the FeRAM devices annealed at different temperatures (the FeRAM device having the ferroelectric material annealed at 650 °C, the FeRAM device having the ferroelectric material annealed at 800 °C, and the FeRAM device having the ferroelectric material annealed at 1000 °C), the polarization window increases with increasing operating temperature (e.g., the polarization window at 470 K is larger than the polarization window at 80 K). However, the present disclosure is not limited to the above-referenced values and the FeRAM device according to one or more embodiments may have any other suitable polarization window (e.g., ranging from approximately +15 P to −15 P to approximately +30 P to −30 P) and any other suitable remnant polarization Pr (e.g., in a range from approximately 10 μC/cm² to approximately 25 μC/cm²). Although FIG. 2A depicts example annealing temperatures (or temperature ranges) and example materials utilized for the ferroelectric material, the present disclosure is not limited to those annealing temperatures and ferroelectric materials, and FIG. 2A is intended solely to illustrate that increasing annealing temperatures increases the ferroelectric polarization of the ferroelectric material. Additionally, increasing the annealing temperature may be applied to any suitable ferroelectric material, such as PZT or HfO₂.

FIG. 2B is a graph comparing the polarization P (in micro coulombs per square centimeter μC/cm²) as a function voltage (V) applied to the ferroelectric material of FeRAM devices having different ferroelectric capacitor thicknesses according to embodiments of the present disclosure. As illustrated in FIG. 2B, reducing the thickness of the ferroelectric capacitor from 6 nm to 5 nm reduced the operating voltage range from approximately −0.87 V to approximately +0.87 V to an operating voltage range of approximately −0.75 V to +0.75 V. Additionally, as illustrated in FIG. 2B, reducing the thickness of the ferroelectric capacitor from 5 nm to 4 nm reduced the operating voltage range from approximately −0.75 V to approximately +0.75 V to an operating voltage range of approximately −0.5 V to +0.5 V. Furthermore, as illustrated in FIG. 2B, reducing the thickness of the ferroelectric capacitor from 4 nm to 3 nm reduced the operating voltage range from approximately −0.5 V to approximately +0.5 V to an operating voltage range of approximately −0.3 V to +0.3 V. Accordingly, in one or more embodiments, the ferroelectric capacitor 103 may have a thickness of approximately 4 nm or less (e.g., approximately 3 nm or less) such that the operating voltage range is approximately 1 V or less. Although FIG. 2B depicts example thicknesses utilized for the ferroelectric material, the present disclosure is not limited to these thicknesses, any suitable thickness may be utilized for the ferroelectric material, and FIG. 2B is intended solely to illustrate that reducing the thickness of the ferroelectric material reduces the operating voltage of the FeRAM device.

In one or more embodiments, the FeRAM device 100 according to one or more embodiments of the present disclosure may have a read/write endurance of at least a predetermined endurance threshold (e.g., up to approximately 10¹⁵ cycles or more) and data retention without power (i.e., non-volatility) for up to a predetermined data retention threshold (e.g., approximately 100 years or more, such as approximately 121 years, at approximately 85 °C, or for up to approximately 10,000 hours or more, such as approximately 11,000 hours, at approximately 125 °C). In one or more embodiments, the FeRAM device 100 according to one or more embodiments of the present disclosure may have a write speed of less than a predetermined write speed threshold (e.g., approximately 1 nanosecond (ns)), a read speed of less than a predetermined read speed threshold (e.g., approximately 1 ns), a switching voltage in a range from approximately 0.4 V to approximately 0.6 V (e.g., approximately 0.5 V or less), a read energy of less than a predetermined read energy threshold (e.g., approximately 2 femtojoules (fJ)), and a cell write energy of less than a predetermined write energy threshold (e.g., approximately 1 femtojoules (fJ)). However, the present disclosure is not limited thereto, and the FeRAM device according to one or more embodiments may exhibit any other suitable read/write endurance, data retention without power, write speed, read speed, read energy, and cell write energy depending, for instance, on the annealing temperature, the material utilized for the ferroelectric material, and the thickness of the ferroelectric material. In one or more embodiments, the FeRAM device according to one or more embodiments of the present disclosure may exhibit a read/write endurance, a data retention without power, a write speed, a read speed, a read energy, and/or a cell write energy that is/are the same as (or substantially the same as) other memory devices, such as a related art SRAM device. Accordingly, the FeRAM device according to one or more embodiments of the present disclosure may have substantially the same or similar performance as a related art SRAM device but with approximately 50% area scaling compared to the SRAM device at one or more state-of-the-art technology nodes. In one or more embodiments, the FeRAM device according to one or more embodiments of the present disclosure may exhibit a read/write endurance, a data retention without power, a write speed, a read speed, a read energy, and/or a cell write energy that is/are typical for other FeRAM devices.

Additionally, in one or more embodiments, the FeRAM device 100 includes a single V_{DD} rail including both VDD and VSS voltage supplies coupled to the FeRAM device. Accordingly, the FeRAM device 100 of the present disclosure may consume less power than a related art SRAM device that utilizes multiple positive voltage supply lines (i.e., multiple V_{DD} rails).

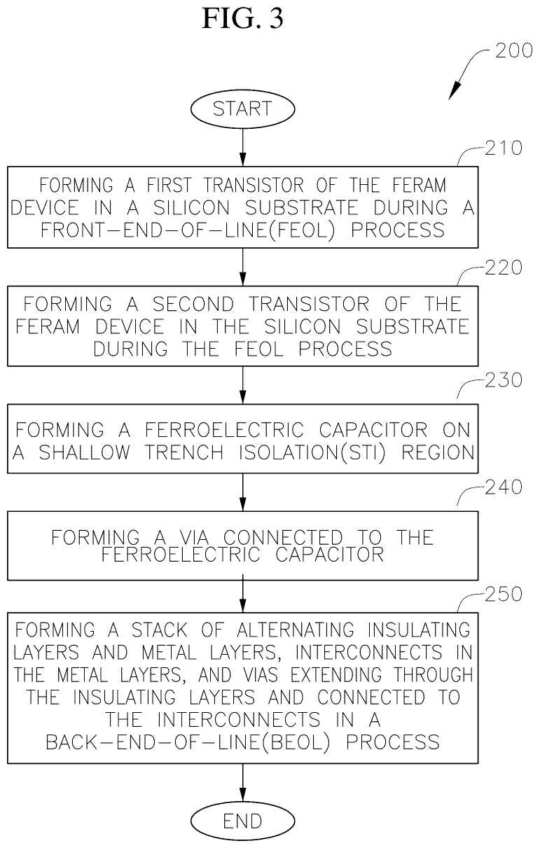

FIG. 3 is a flowchart illustrating tasks of aspects of a method 200 of manufacturing a semiconductor device including a two-transistor one-capacitor ferroelectric random-access memory (FeRAM) device according to one embodiment of the present disclosure. In the illustrated embodiment, the method 200 includes a task 210 of forming a first transistor of the FeRAM device in (or on) a silicon substrate utilizing a front-end-of-line (FEOL) process. The first transistor formed in task 210 includes a source, a drain, a channel, and a gate on the channel. The task 210 of forming the first transistor may include etching recesses into a layer (e.g., applying a photoresist material, exposing the photoresist to ultraviolet light to form a mask, and etching in the areas not protected by the mask), depositing material into the recesses (e.g., atomic layer deposition (ALD), chemical vapor deposition (CVD) and/or physical vapor deposition (PVD)), and doping the deposited material.

In the illustrated embodiment, the method 200 includes a task 220 of forming a second transistor of the FeRAM device in (or on) the silicon substrate utillizing the FEOL process. The second transistor formed in task 220 includes a source, a drain, a channel, and a gate on the channel. The task 220 of forming the second transistor may include etching recesses into a layer (e.g., applying a photoresist material, exposing the photoresist to ultraviolet light to form a mask, and etching in the areas not protected by the mask), depositing material into the recesses (e.g., ALD, CVD, and/or PVD), and doping the deposited material. In one or more embodiments, the first and second transistors formed in tasks 210, 220 are adjacent to (e.g., on opposite sides of) a shallow trench isolation (STI) region in the silicon substrate. The STI region may be a single-diffusion break (SDB) or a double-diffusion break (DDB) or any other suitable region of insulating material (e.g., a trench filled with an oxide material) that is configured to electrically isolate the first transistor from the second transistor and thereby prevent (or at least mitigate) electrical leakage therebetween.

In the illustrated embodiment, the method 200 also includes a task 230 of forming a ferroelectric capacitor on the STI region. The ferroelectric capacitor formed in task 230 includes a pair of electrodes (e.g., upper and lower plates spaced apart from each other) and a ferroelectric layer between the pair of electrodes (i.e., the ferroelectric layer is sandwiched between the pair of electrodes). In one or more embodiments, the electrodes may be formed of (or include) any suitable material, such as metal (e.g., platinum (Pt), ruthenium (Ru), iridium (Ir), tungsten (W), and/or Titanium nitride (TiN)), a conductive oxide (e.g., ruthenium dioxide (RuO₂), molybdenum dioxide (MoO₂), and/or Indium tin oxide (ITO)), graphite, few-layer graphene (FLG), or combinations thereof. The ferroelectric layer may be formed of (or include) any suitable ferroelectric material, such as hafnium-zirconium oxide (HZO), lead zirconate titanate (PZT), bismuth ferrite (BiFeO3), lithium niobate (LiNbO3), barium titanate (BaTiO3), triglycine sulfate, lithium tantalate, polyvinylidene fluoride (PVDF), and/or Rochelle salt. In one or more embodiments, the task 230 of forming the ferroelectric capacitor includes thermal annealing the ferroelectric layer. In one or more embodiments, the ferroelectric layer may be annealed at a temperature of approximately 500 °C or more (e.g., approximately 650 °C or more, approximately 800 °C or more, or approximately 1000 °C or more). In one or more embodiments, the ferroelectric layer may be annealed at any other suitable temperature. As shown in the graph of FIG. 2A, annealing the ferroelectric layer is configured to increase ferroelectric (Fe) polarization and enlarge the memory window of the FeRAM device. In one or more embodiments, the annealing temperature may be selected based on a combination of experimental results and simulations.

In the illustrated embodiment, the method 200 also includes a task 240 of forming a via connected to the ferroelectric capacitor formed in task 230. In one or more embodiments, the task 240 of forming the via may include etching an opening in a dielectric layer and depositing a metal in the opening.

In the illustrated embodiment, the method 200 also includes a task 250 of forming a stack of alternating insulating layers (e.g., oxide layers) and metal layers, forming a plurality of interconnects in the metal layers, and forming a plurality of vias extending through the insulating layers and connected to the interconnects in a back-end-of-line (BEOL) process after the FEOL process to complete the semiconductor device. In one or more embodiments, the task 250 may include depositing the alternating insulating layers and metal layers by ALD, CVD, PVD, or any other suitable technique, etching the metal layers to form the interconnects (e.g., applying a photoresist material on the metal layers, exposing the photoresist to ultraviolet light to form a mask, and etching in the areas not protected by the mask), etching the insulating layers to form openings extending through the insulating layers (e.g., applying a photoresist material on the insulating layers, exposing the photoresist to ultraviolet light to form a mask, and etching in the areas not protected by the mask), and depositing a conductive material in the recesses to form the vias.

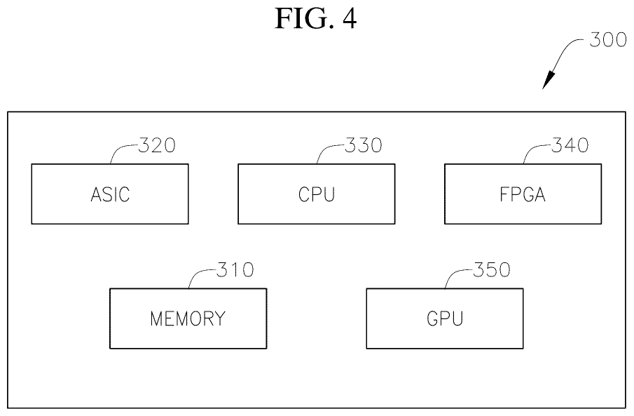

FIG. 4 illustrates an electronic device 300 including a FeRAM device (e.g., the embodiment of the FeRAM device 100 illustrated in FIG. 1 or manufactured according to the method 200 illustrated in FIG. 3) according to one or more embodiments of the present disclosure. In the illustrated embodiment, the electronic device 300 may include at least one of a memory 310, an application specific integrated circuit (ASIC) 320, a central processing unit (CPU) 330, a field programmable gate array (FPGA) 340, and a graphics processing unit (GPU) 350. The FeRAM device may be included in at least one of the memory 310, the ASIC 320, the FPGA 340, and/or the GPU 350.

The electronic device 300 may also include a user interface 360 configured to input data to the electronic device 300, or output data from the electronic device 300. For example, the user interface 360 may include a keyboard, a touch pad, a touch screen, a mouse, a scanner, a voice detector, a liquid crystal display (LCD), a micro light-emitting device (LED), an organic light-emitting diode (OLED) device, an active-matrix light-emitting diode (AMOLED) device, a printer, a lighting, or various other input/output devices without limitation. The memory 310 may store operational codes (i.e., computer readable/executable instructions) of at least one of the ASIC 320, the CPU 330, the FPGA 340, and/or the GPU 350, data processed by at least one of the ASIC 320, the CPU 330, the FPGA 340, and/or the GPU 350, or data received from an external device.

The electronic device 300 may be a stand-alone system that uses the FeRAM device to perform one or more electrical functions. Alternatively, the electronic device 300 may be a subcomponent of a larger system. For example, the electronic device 300 may be part of a computer, a cellular phone, a personal digital assistant (PDA), a digital video camera (DVC), a server, or other electronic communication device. Alternatively, the electronic device 300 may be the memory 310, the ASIC 320, the CPU 330, the FPGA 340, the GPU 350, a network interface card, or other signal processing card that can be inserted or included in a computer or other larger system.

The electronic or electric devices and/or any other relevant devices or components according to embodiments of the present disclosure described herein may be implemented utilizing any suitable hardware, firmware (e.g. an application-specific integrated circuit), software, or a combination of software, firmware, and hardware. For example, the various components of these devices may be formed on one integrated circuit (IC) chip or on separate IC chips. Further, the various components of these devices may be implemented on a flexible printed circuit film, a tape carrier package (TCP), a printed circuit board (PCB), or formed on one substrate.

Further, the various components of these devices may be a process or thread, running on one or more processors, in one or more computing devices, executing computer program instructions and interacting with other system components for performing the various functionalities described herein. The computer program instructions are stored in a memory which may be implemented in a computing device using a standard memory device, such as, for example, a random-access memory (RAM). The computer program instructions may also be stored in other non-transitory computer readable media such as, for example, a CD-ROM, flash drive, or the like. Also, a person of skill in the art should recognize that the functionality of various computing devices may be combined or integrated into a single computing device, or the functionality of a particular computing device may be distributed across one or more other computing devices without departing from the spirit and scope of the embodiments of the present disclosure.

Any of the functionalities described herein, including any of the functionalities that may be implemented with a host, a device, and/or the like or a combination thereof, may be implemented with hardware, software, firmware, or any combination thereof including, for example, hardware and/or software combinational logic, sequential logic, timers, counters, registers, state machines, volatile memories such as dynamic RAM (DRAM) and/or static RAM (SRAM), nonvolatile memory including flash memory, persistent memory such as cross-gridded nonvolatile memory, memory with bulk resistance change, phase change memory (PCM), and/or the like and/or any combination thereof, complex programmable logic devices (CPLDs), field programmable gate arrays (FPGAs), application-specific ICs (ASICs), central processing units (CPUs) including complex instruction set computer (CISC) processors and/or reduced instruction set computer (RISC) processors, graphics processing units (GPUs), neural processing units (NPUs), tensor processing units (TPUs), data processing units (DPUs), and/or the like, executing instructions stored in any type of memory. In some embodiments, one or more components may be implemented as a system-on-a-chip (SoC).

Any of the computational devices disclosed herein may be implemented in any form factor, such as 3.5 inch, 2.5 inch, 1.8 inch, M.2, Enterprise and Data Center Standard Form Factor (EDSFF), NF1, and/or the like, using any connector configuration such as Serial Advanced Technology Attachment (SATA), Small Computer System Interface (SCSI), Serial Attached SCSI (SAS), U.2, and/or the like. Any of the computational devices disclosed herein may be implemented entirely or partially with, and/or used in connection with, a server chassis, server rack, data room, data center, edge data center, mobile edge data center, and/or any combinations thereof.

Any of the devices disclosed herein that may be implemented as storage devices may be implemented with any type of nonvolatile storage media based on solid-state media, magnetic media, optical media, and/or the like. For example, in some embodiments, a storage device (e.g., a computational storage device) may be implemented as an SSD based on not-AND (NAND) flash memory, persistent memory such as cross-gridded nonvolatile memory, memory with bulk resistance change, PCM, and/or the like, or any combination thereof.

Any of the communication connections and/or communication interfaces disclosed herein may be implemented with one or more interconnects, one or more networks, a network of networks (e.g., the Internet), and/or the like, or a combination thereof, using any type of interface and/or protocol. Examples include Peripheral Component Interconnect Express (PCIe), non-volatile memory express (NVMe), NVMe-over-fabric (NVMe-oF), Ethernet, Transmission Control Protocol/Internet Protocol (TCP/IP), Direct Memory Access (DMA) Remote DMA (RDMA), RDMA over Converged Ethernet (ROCE), FibreChannel, InfiniBand, SATA, SCSI, SAS, Internet Wide Area RDMA Protocol (iWARP), and/or a coherent protocol, such as Compute Express Link (CXL), CXL. mem, CXL.cache, CXL. IO and/or the like, Gen-Z, Open Coherent Accelerator Processor Interface (OpenCAPI), Cache Coherent Interconnect for Accelerators (CCIX), and/or the like, Advanced eXtensible Interface (AXI), any generation of wireless network including 2G, 3G, 4G, 5G, 6G, and/or the like, any generation of Wi-Fi, Bluetooth, near-field communication (NFC), and/or the like, or any combination thereof.

In some embodiments, a software stack may include a communication layer that may implement one or more communication interfaces, protocols, and/or the like such as PCIe, NVMe, CXL, Ethernet, NVMe-oF, TCP/IP, and/or the like, to enable a host and/or an application running on the host to communicate with a computational device or a storage device.

While this specification may contain many specific implementation details, the implementation details should not be construed as limitations on the scope of any claimed subject matter, but rather be construed as descriptions of features specific to particular embodiments. Certain features that are described in this specification in the context of separate embodiments may also be implemented in combination in a single embodiment. Conversely, various features that are described in the context of a single embodiment may also be implemented in multiple embodiments separately or in any suitable subcombination. Moreover, although features may be described above as acting in certain combinations and even initially claimed as such, one or more features from a claimed combination may in some cases be excised from the combination, and the claimed combination may be directed to a subcombination or variation of a subcombination.

Similarly, while operations are depicted in the drawings in a particular order, this should not be understood as requiring that such operations be performed in the particular order shown or in sequential order, or that all illustrated operations be performed, to achieve desirable results. In certain circumstances, multitasking and parallel processing may be advantageous. Moreover, the separation of various system components in the embodiments described above should not be understood as requiring such separation in all embodiments, and it should be understood that the described program components and systems can generally be integrated together in a single software product or packaged into multiple software products.

Thus, particular embodiments of the subject matter have been described herein. Other embodiments are within the scope of the following claims. In some cases, the actions set forth in the claims may be performed in a different order and still achieve desirable results. Additionally, the processes depicted in the accompanying figures do not necessarily require the particular order shown, or sequential order, to achieve desirable results. In certain implementations, multitasking and parallel processing may be advantageous.

As will be recognized by those skilled in the art, the innovative concepts described herein may be modified and varied over a wide range of applications. Accordingly, the scope of claimed subject matter should not be limited to any of the specific exemplary teachings discussed above, but is instead defined by the following claims.

What is claimed is:

1. A semiconductor device comprising:
a substrate comprising a shallow trench isolation region; and
a ferroelectric random-access memory device comprising a first transistor, a second transistor, and a ferroelectric capacitor,
wherein the ferroelectric capacitor is on the shallow trench isolation region, and
wherein the first and second transistors are adjacent to the shallow trench isolation region.

2. The semiconductor device of claim 1, wherein the shallow trench isolation region comprises a dielectric material.

3. The semiconductor device of claim 2, wherein the shallow trench isolation region is a single diffusion break or a double-diffusion break.

4. The semiconductor device of claim 1, wherein a width of the shallow trench isolation region is equal to or less than a threshold distance.

5. The semiconductor device of claim 4, wherein the threshold distance is approximately 1 contacted poly pitch (CPP).

6. The semiconductor device of claim 1, further comprising a single V_{DD} rail including both VDD and VSS voltage supplies coupled to the ferroelectric random-access memory device.

7. The semiconductor device of claim 1, wherein the ferroelectric capacitor comprises a ferroelectric layer between a pair of electrodes.

8. The semiconductor device of claim 7, wherein the ferroelectric layer comprises a ferroelectric material selected from the group consisting of hafnium-zirconium oxide (HZO), lead zirconate titanate (PZT), bismuth ferrite (BiFeO3), lithium niobate (LiNbO3), barium titanate (BaTiO3), triglycine sulfate, lithium tantalate, polyvinylidene fluoride (PVDF), and Rochelle salt.

9. The semiconductor device of claim 7, wherein each electrode of the pair of electrodes comprises a material selected from the group consisting of a metal, a conductive oxide, and graphene.

10. An electronic device comprising the semiconductor device of claim 1, wherein the electronic device is selected from the group consisting of a memory, an application specific integrated circuit (ASIC), a central processing unit (CPU), a field programmable gate array (FPGA), and a graphics processing unit (GPU).

11. A method of manufacturing a semiconductor device, the method comprising:
forming a first transistor of a ferroelectric random-access memory device on a substrate during a front-end-of-line process;
forming a second transistor of the ferroelectric random-access memory device on the substrate during the front-end-of-line process, the first transistor and the second transistor being adjacent to a shallow trench isolation region in the substrate; and
forming a ferroelectric capacitor on the shallow trench isolation region, the forming of the ferroelectric capacitor comprising forming a pair of electrodes and forming an annealed ferroelectric layer between the pair of electrodes.

12. The method of claim 11, wherein forming the annealed ferroelectric layer is performed at a temperature selected from the group consisting of at least approximately 500 °C, at least approximately 650 °C, at least approximately 800 °C, and at least approximately 1000 °C.

13. The method of claim 11, wherein the annealed ferroelectric layer comprises a ferroelectric material selected from the group consisting of hafnium-zirconium oxide (HZO), lead zirconate titanate (PZT), bismuth ferrite (BiFeO3), lithium niobate (LiNbO3), barium titanate (BaTiO3), triglycine sulfate, lithium tantalate, polyvinylidene fluoride (PVDF), and Rochelle salt.

14. The method of claim 11, further comprising forming a plurality of interconnects in a back-end-of-line process after the front-end-of-line process.

15. A system comprising:
an electronic device comprising a semiconductor device, the semiconductor device comprising:
a substrate comprising a shallow trench isolation region; and
a ferroelectric random-access memory device comprising a first transistor, a second transistor, and a ferroelectric capacitor,
wherein the ferroelectric capacitor is on the shallow trench isolation region, and
wherein the first and second transistors are adjacent to the shallow trench isolation region.

16. The system of claim 15, wherein the shallow trench isolation region comprises a single diffusion break or a double-diffusion break.

17. The system of claim 15, wherein a width of the shallow trench isolation region is equal to or less than a threshold distance.

18. The system of claim 15, wherein the semiconductor device further comprises a single V_{DD} rail including both VDD and VSS voltage supplies coupled to the ferroelectric random-access memory device.

19. The system of claim 15, wherein a ferroelectric layer of the ferroelectric capacitor comprises a ferroelectric material selected from the group consisting of hafnium-zirconium oxide (HZO), lead zirconate titanate (PZT), bismuth ferrite (BiFeO3), lithium niobate (LiNbO3), barium titanate (BaTiO3), triglycine sulfate, lithium tantalate, polyvinylidene fluoride (PVDF), and Rochelle salt.

20. The system of claim 15, wherein the electronic device is selected from the group consisting of a memory, an application specific integrated circuit (ASIC), a central processing unit (CPU), a field programmable gate array (FPGA), and a graphics processing unit (GPU).
